(19) United States
(12) Patent Application Publication
(10) Pub. No.: US 2026/0204588 A1
(43) Pub. Date: Jul. 16, 2026

(54) METHOD OF MANUFACTURING METAL LAYER AND METAL LAYER FOR LITHIUM BATTERY CURRENT COLLECTOR

(71) Applicant: Dong-A University Research Foundation For Industry-Academy Cooperation, Busan (KR)

(72) Inventors: Jung Han KIM, Changwon-si (KR); Han Kyun SHIN, Changwon-si (KR); Ki Young LEE, Ulsan (KR); Eun Gi OH, Busan (KR)

(73) Assignee: Dong-A University Research Foundation For Industry-Academy Cooperation, Busan (KR)

(21) Appl. No.: 19/383,119

(22) Filed: Nov. 7, 2025

(30) Foreign Application Priority Data
Nov. 13, 2024 (KR) 10-2024-0160873

(51) Int. Cl. H01M 4/66; H01M 4/02; H01M 10/052

(52) U.S. Cl. CPC H01M 4/667; H01M 4/661; H01M 10/052; H01M 2004/021; H01M 2004/027

(57) ABSTRACT

A method of manufacturing a metal layer, a metal layer, etc. are proposed. The method includes a copper foil manufacturing step of forming a copper layer as an electroplated layer using a plating solution containing a copper precursor and a leveler, and a coating step of forming a gold coating layer on a surface of the copper layer, thereby manufacturing a metal layer. The leveler includes JGB (Janus green B, C₃₀H₃₁ClN₆). The plating solution contains the leveler in an amount of greater than 10 μmol to equal to or less than 40 μmol based on 1 mol of copper in the copper precursor. The metal layer has a roughness average (Ra) of equal to or less than 50 nm, as measured on a surface of the gold coating layer.

### CROSS REFERENCE TO RELATED APPLICATION

The present application claims priority to Korean Patent Application No. 10-2024-0160873, filed Nov. 13, 2024, the entire contents of which is incorporated herein for all purposes by this reference.

### BACKGROUND OF THE INVENTION

### Field of the Invention

The present disclosure relates to a method of manufacturing a metal layer that can be used as a negative electrode current collector of a lithium battery, and exhibits improved stability and long-term durability.

### Description of the Related Art

Secondary batteries and fuel cells are generally equipped with a negative electrode current collector and a positive electrode current collector, with an electrolyte or active material between the negative electrode current collector and the positive electrode current collector. For the negative electrode collector of secondary batteries and fuel cells, metal thin plates made of metals such as nickel and copper are used.

The use of secondary batteries and fuel cells as clean energy sources has been continuously increasing across various industries, including automobiles and energy. Accordingly, the demand for secondary batteries and fuel cells that maintain stable performance over long-term use is also growing. Examples of the related art include Korean Patent Application Publication No. 10-2024-0039471 and Korean Patent No. 10-2176482.

The foregoing is intended merely to aid in the understanding of the background of the present disclosure, and is not intended to mean that the present disclosure falls within the purview of the related art that is already known to those skilled in the art.

### SUMMARY OF THE INVENTION

Accordingly, the present disclosure has been made keeping in mind the above problems occurring in the related art, and one objective of the present disclosure is to provide a metal layer having controlled surface characteristics and including a gold coating layer and a copper layer, and a method of manufacturing the same.

Another objective of the present disclosure is to provide a metal layer that is highly suitable for use as a negative electrode current collector of a lithium battery by suppressing dendrite growth during ion intercalation and deintercalation, and a method of manufacturing the same.

In order to achieve the above objectives, according to one aspect of the present disclosure, there is provided a method of manufacturing a metal layer, the method including: a copper foil manufacturing step of forming a copper layer as an electroplated layer using a plating solution containing a copper precursor and a leveler; and a coating step of forming a gold coating layer on a surface of the copper layer, thereby manufacturing a metal layer.

The leveler may include JGB (Janus green B, C₃₀H₃₁ClN₆).

The plating solution may contain the leveler in an amount of greater than 10 μmol to equal to or less than 40 μmol based on 1 mol of copper in the copper precursor.

The metal layer may have a roughness average (Ra) of equal to or less than 50 nm, as measured on a surface of the gold coating layer.

The coating step may be carried out by a sputtering method using a gold target.

The gold coating layer may have a thickness of equal to or less than 6 nm.

The metal layer may have a ten point average roughness (Rz) of equal to or less than 500 nm.

The gold coating layer may have a surface structure in which gold nanoparticles are embedded.

The metal layer may suppress lithium dendrite growth on the metal layer when used as a negative electrode current collector of a lithium battery.

According to another aspect of the present disclosure, there is provided a metal layer for a lithium battery current collector, the metal layer including: a copper layer; and a gold coating layer disposed on a surface of the copper layer, wherein the metal layer may have a roughness average (Ra) of equal to or less than 50 nm, as measured on a surface of the gold coating layer.

The metal layer, when used as a negative electrode current collector of a lithium battery, may maintain a voltage range of −1.5 to +1.5 V relative to a reference voltage during cycling performance testing of 0 to 500 hours.

The method of manufacturing the metal layer according to the present disclosure enables a metal layer, having controlled surface characteristics and including a gold coating layer and a copper layer, to be manufactured with excellent reproducibility.

The metal layer according to the present disclosure can suppress dendrite growth during lithium ion intercalation and deintercalation, making it highly suitable for use as a negative electrode current collector of a lithium battery.

The copper layer according to the present disclosure can be utilized as a negative electrode current collector of a lithium battery, contributing to the production of lithium batteries with enhanced stability and durability.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 illustrates images of surfaces of copper layers manufactured in Preparation Examples 1 -1 to 1-4;

FIG. 2A illustrates AFM images and Ra, Rq, and Rz measurement results of Comparative Example 3, Example 1, and Comparative Example 1;

FIG. 2B illustrates SEM images of surfaces of samples from Comparative Example 1 and Example 1; and

FIG. 3 illustrates a graph showing the long-term cycling performance evaluation results of symmetric cells fabricated using samples from Examples and Comparative Examples.

### DETAILED DESCRIPTION OF THE INVENTION

Hereinbelow, exemplary embodiments of the present disclosure will be described in detail with reference to the accompanying drawings such that the disclosure can be easily embodied by one of ordinary skill in the art to which this disclosure belongs. The present disclosure may, however, be embodied in many different forms and should not be construed as being limited to the embodiments set forth herein. Throughout the drawings, the same reference numerals will refer to the same or like parts.

The inventors of the present disclosure conceived that coating a surface of a copper foil with a lithiophilic material such as gold (Au) can effectively suppress the growth of lithium dendrites by lowering the nucleation overpotential of lithium ions during a charge/discharge process of a secondary battery, and presented the specific details based on this concept. The present disclosure provides a metal layer having a copper foil (copper layer) with controlled surface characteristics on which a gold coating layer is formed such that the surface roughness of the resulting metal layer is maintained below a specified level. Additionally, the present disclosure provides a method of manufacturing the metal layer with high reproducibility.

Hereinafter, detailed descriptions will be given of exemplary embodiments of the present disclosure.

In order to achieve the above objectives, a method of manufacturing a metal layer according to an embodiment of the present disclosure includes: a copper foil manufacturing step of forming a copper layer as an electroplated layer using a plating solution containing a copper precursor and a leveler; and a coating step of forming a gold coating layer on a surface of the copper layer, thereby manufacturing a metal layer.

The copper precursor may, for example, be copper sulfate.

The leveler may include JGB (Janus green B, C₃₀H₃₁ClN₆).

When the copper layer is formed by a plating process, the leveler adsorbs onto a surface to be plated, thereby increasing the local overpotential and reducing the plating rate at the site of adsorption, which helps to form a relatively smooth surface. Therefore, the application of the leveler may increase the overvoltage of protruding areas having the leveler adsorbed during electroplating, locally reducing the plating rate relatively, while current may be redistributed toward recessed areas, causing the plating to accelerate in those areas and thereby mitigating surface roughness.

The plating solution may contain the leveler in an amount of greater than 10 μmol to equal to or less than 40 μmol based on 1 mol of copper in the copper precursor.

The amount of the leveler may be equal to or greater than 14 μmol or equal to or greater than 18 μmol based on 1 mole of copper in the copper precursor. Additionally, the amount of the leveler may be equal to or less than 35 μmol, equal to or less than 30 μmol, or equal to or less than 25 μmol, based on 1 mole of copper in the copper precursor. When the leveler is included within the above amount range, a copper layer having an appropriate level of surface roughness as intended in the present disclosure may be manufactured. A too small amount of the leveler may result in the gloss of the copper layer surface not being clearly exhibited. On the other hand, an excessive amount of the leveler may cause a rough surface due to an overly suppressive effect.

The plating solution may further contain a plating inhibitor.

The plating inhibitor may include polyethylene glycol.

The plating solution may contain the plating inhibitor in an amount of 80 to 110 μmol based on 1 mol of copper in the copper precursor.

The plating solution may further contain a plating accelerator.

The plating accelerator may include SPS [bis-(3-sulfopropyl)disulfide].

The plating solution may contain the plating accelerator in an amount of 35 to 60 μmol based on 1 mol of copper in the copper precursor.

The formation of the electroplated layer may, for example, be carried out by immersing a substrate and electrodes in a plating solution and applying a current to the electrodes. The electrodes may, for example, be made of phosphorized copper and a titanium plate, but are not limited thereto. Current density may be adjusted depending on the reactive surface area between the plating solution and the substrate.

A detailed description of the copper layer formed in this manner will be provided later.

The coating step may be carried out by a sputtering method using a gold target.

The gold coating layer may also be formed by methods such as chemical vapor deposition (CVD) or evaporation. However, considering that these methods require high vacuum or significantly long processing times, forming the gold coating layer by sputtering is more advantageous. Additionally, in the case of electroplating using gold, it may be cumbersome to selectively form a plating layer only on the intended area, and there is a possibility that a significant variation in thickness may result.

On the other hand, when a sputtering method is adopted in the coating step, a gold coating layer in the form of nanoparticles may be formed on the copper layer with excellent reproducibility. Furthermore, the formation of a thin gold coating layer through sputtering enables the creation of a nanoscale thin gold coating layer, allowing the gold coating to be formed while substantially maintaining the overall surface roughness of the copper layer. A detailed description of the gold coating layer will be provided later.

The metal layer prepared in this manner may be advantageously used as a negative electrode current collector of a lithium secondary battery.

In order to achieve the above objectives, a metal layer according to another embodiment of the present disclosure, which is useful as a lithium battery current collector, includes: a copper layer; and a gold coating layer disposed on a surface of the copper layer.

The copper layer may be an electroplated copper layer.

The copper layer may have a controlled surface roughness on at least one surface thereof.

A detailed description of the surface roughness of the copper layer is omitted here to avoid redundancy and will be provided later in connection with the metal layer.

The copper layer may have a thickness of equal to or greater than 5 μm or equal to or greater than 10 μm. The thickness may be equal to or less than 30 μm.

The gold coating layer may have a form in which gold nanoparticles are arranged with a portion thereof embedded.

The gold coating layer may have a thickness of equal to or less than 6 nm, equal to or less than 5 nm, or equal to or less than 4 nm. The thickness may be equal to or greater than 1 nm.

The metal layer has a controlled surface roughness.

The surface roughness may be measured by atomic force microscopy (AFM) or the like.

The metal layer may have a roughness average (Ra) of equal to or less than 50 nm, as measured on a surface of the gold coating layer. The Ra may be equal to or less than 40 nm, equal to or less than 35 nm, equal to or less than 30 nm, equal to or less than 25 nm, or equal to or less than 20 nm. The Ra may be equal to or greater than 5 nm or equal to or greater than 10 nm. The metal layer having a surface roughness within the above range is advantageous for use as a negative electrode current collector of a lithium ion battery and may exhibit excellent stability.

The metal layer may have a ten point average roughness (Rz) of equal to or less than 500 nm. The Rz may be equal to or less than 450 nm, equal to or less than 400 nm, equal to or less than 350 nm, or equal to or less than 300 nm. The Rz may be equal to or greater than 200 nm. The metal layer having a surface roughness within the above range is advantageous for use as a negative electrode current collector of a lithium ion battery and may exhibit excellent stability.

The metal layer may have a root-mean-squared roughness (Rq) of equal to or less than 70 nm, equal to or less than 60 nm, equal to or less than 50 nm, or equal to or less than 40 nm. The Rq may be equal to or greater than 10 nm. The metal layer having a surface roughness within the above range is advantageous for use as a negative electrode current collector of a lithium ion battery and may exhibit excellent stability.

The metal layer may suppress lithium dendrite growth on the metal layer when used as a negative electrode current collector of a lithium battery.

The metal layer, when used as a negative electrode current collector, may maintain a voltage range of −1.5 to +1.5 V relative to a reference voltage during cycling performance testing of 0 to 500 hours.

The metal layer may be utilized as a negative electrode current collector of a lithium battery, and exhibit improved stability and durability. Furthermore, it may help suppress dendrite growth during lithium ion intercalation and deintercalation, making it highly suitable for use as a negative electrode current collector of a lithium battery.

Hereinafter, the present disclosure will be described in more detail with reference to specific examples. The following examples are provided merely to facilitate understanding of the disclosure and are not intended to limit the scope of the present disclosure.

### Manufacturing of Copper Layer (Copper Foil Manufacturing Step)

### Preparation Example 1-1: Application of 20 μM JGB

A plating solution was prepared by mixing copper sulfate, sulfuric acid, chloride ions (from NaCl), polyethylene glycol as a plating inhibitor, SPS [bis-(3-sulfopropyl)disulfide] as a plating accelerator, and JGB (Janus Green B, C₃₀H₃₁ClN₆) as a leveler. The plating solution contained 1 M of copper ions, 1 M of sulfuric acid, 30 ppm of chloride ions (based on molar concentration), 50 μM of SPS, 100 μM of polyethylene glycol, and 20 μM of JGB in the above molar ratios.

A substrate, an oxidation electrode, and a reduction electrode were immersed in the plating solution, and electroplating was carried out using the oxidation electrode and the reduction electrode. As the positive electrode, phosphorized copper was used and, as the negative electrode, a titanium plate was used. A current was applied to achieve a current density of 100 mA/cm², which can be calculated based on the reactive surface area between the plating solution and the substrate. The current application was performed at 25° C., resulting in a copper plated layer with a thickness of 10 μm (a copper layer of Preparation Example 1-1).

### Preparation Example 1-2: Application of 10 μM JGB

Except that the concentration of JGB was adjusted to 10 μM, a copper plated layer was manufactured in the same manner as in Preparation Example 1-1, which was designated as a copper layer of Preparation Example 1-2.

### Preparation Example 1-3: Application of 50 μM JGB

Except that the concentration of JGB was adjusted to 50 μM, a copper plated layer was manufactured in the same manner as in Preparation Example 1-1, which was designated as a copper layer of Preparation Example 1-3.

### Preparation Example 1-4: Application of 100 μM JGB

Except that the concentration of JGB was adjusted to 100 μM, a copper plated layer was manufactured in the same manner as in Preparation Example 1-1, which was designated as a copper layer of Preparation Example 1-4.

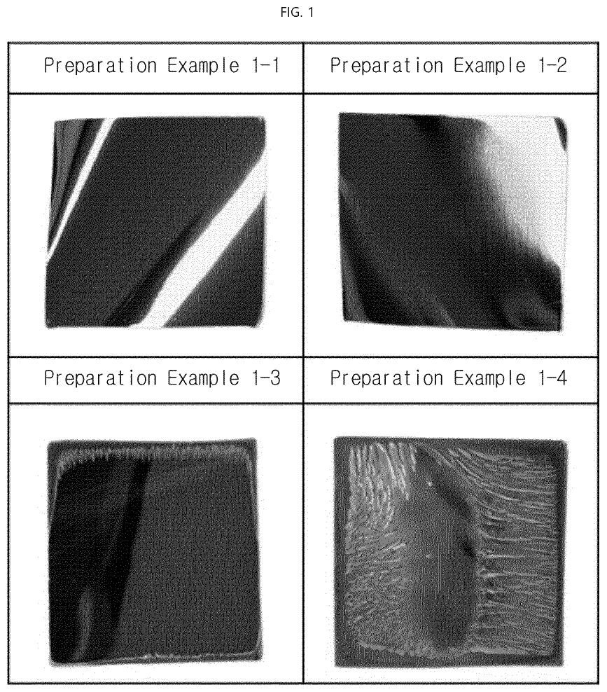

FIG. 1 illustrates images showing a visual comparison of surfaces of the copper layers of Preparation Examples 1-1 to 1-4. Referring to FIG. 1, the copper layer of Preparation Example 1-1 exhibited excellent surface gloss and smoothness. On the contrary, the copper layer of Preparation Example 1-2 showed poor surface gloss, while those of Preparation Examples 1-3 and 1-4 exhibited rough surfaces. Therefore, the copper layer of Preparation Example 1-1 was determined to possess the desired level of surface roughness characteristics intended in the present disclosure and was subsequently used for the manufacturing of a gold coating layer.

### <Example 1>

### Manufacturing of Gold Coating Layer (Coating Step)

A gold coating layer was formed on the copper layer manufactured in Preparation Example 1-1.

Sputtering was performed using the 108 Auto Sputter Coater model from Cressington. The process was carried out under a vacuum atmosphere of 0.05 to 0.1 mbar, with operating conditions of 30 mA for 5 seconds, resulting in the formation of a gold coating layer of approximately 2 nm. The gold coating layer was deposited in a form in which nano-sized particles were partially embedded in a surface. Through this process, a metal layer of Example 1 was manufactured in which the gold coating layer was disposed on the copper layer.

### <Comparative Example 1>

A plating solution was prepared by mixing copper sulfate, sulfuric acid, and chloride ions (from NaCl). The plating solution contained 1 M of copper ions, 1 M of sulfuric acid, and 30 ppm of chloride ions (based on molar concentration) in the above molar ratios.

A substrate, an oxidation electrode, and a reduction electrode were immersed in the plating solution, and electroplating was carried out using the oxidation electrode and the reduction electrode. As the positive electrode, phosphorized copper was used and, as the negative electrode, a titanium plate was used. A current was applied to achieve a current density of 100 mA/cm², which can be calculated based on the reactive surface area between the plating solution and the substrate. The current application was performed at 25° C., resulting in a copper plated layer with a thickness of 10 μm.

A gold coating layer was subsequently formed on the plated layer using the 108 Auto Sputter Coater model from Cressington. The process was carried out under a vacuum atmosphere of 0.05 to 0.1 mbar, with operating conditions of 30 mA for 5 seconds, resulting in the formation of a gold coating layer of approximately 2 nm. The gold coating layer was deposited in a form in which nano-sized particles were partially embedded in a surface. Through this process, a metal layer of Comparative Example 1 was manufactured in which he gold coating layer was disposed on the copper layer.

### <Comparative Example 2>

The copper layer of Preparation Example 1 -1 was used as a metal layer of Comparative Example 2 without forming a gold coating layer thereon.

### <Comparative Example 3>

A commercially available copper layer for a negative electrode current collector without a gold coating layer thereon was used as a metal layer of Comparative Example 3. A metal layer separated from a 2032 half coin cell to be described later was applied.

### Evaluation of Surface Roughness Characteristics

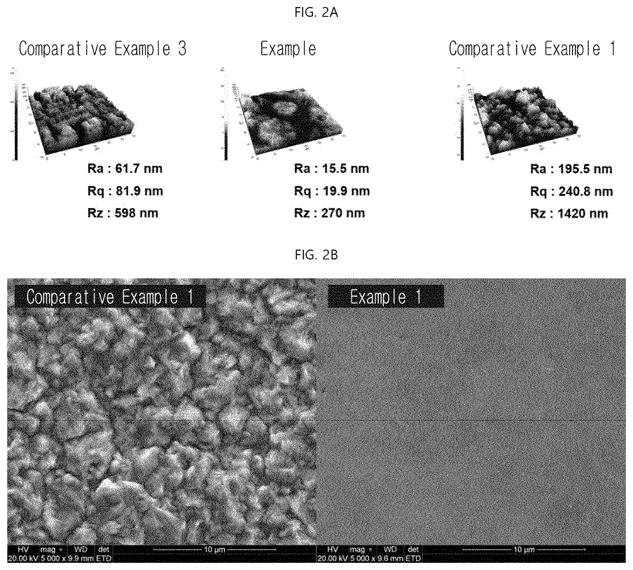

The surface roughness characteristics of samples from Example 1, Comparative Example 1, and Comparative Example 3 were measured using atomic force microscopy (AFM). Additionally, differences in the surface microstructure were observed using a scanning electron microscope (SEM). FIG. 2A illustrates AFM images and Ra, Rq, and Rz measurement results of Comparative Example 3, Example 1, and Comparative Example 1, and FIG. 2B illustrates SEM images of the surfaces of samples from Comparative Example 1 and Example 1. Referring to FIGS. 2A and 2B, Example 1 exhibited a relatively low surface roughness, with an Ra of 15.5 nm, an Rq of 19.9 nm, and an Rz of 270 nm. On the contrary, Comparative Example 1 had an Ra of 195.5 nm, an Rq of 240.8 nm, and an Rz of 1,420 nm, whereas Comparative Example 3 had an Ra of 61.7 nm, an Rq of 81.9 nm, and an Rz of 598 nm. Surface SEM images (scale bar: 10 μm) further confirmed that the comparative examples had very uneven and rough surfaces, whereas Example 1 displayed a smooth surface.

### Evaluation of Long-Term Cycling Performance of Symmetric Cell

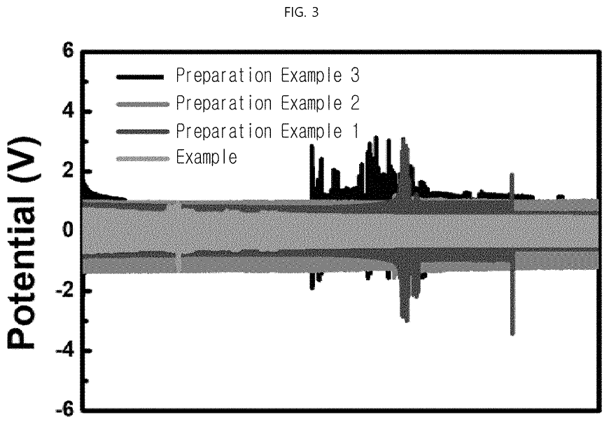

The metal layers of Example 1 and Comparative Examples 1 to 3 were used as positive electrode current collectors to fabricate symmetric cells, and their long-term cycling performance was evaluated. The results are shown in FIG. 3.

The fabrication of the symmetric cells were achieved using 2032 half coin cells. The cells were disassembled at 50% state of charge (SOC). The structure of the disassembled cell consisted of: cell cap-spring-spacer-lithium foil-separator with electrolyte-working electrode-cell can.

The separated working electrode (copper foil) was washed with DMC. Two cleaned electrodes were then used to reassemble coin cells. During this process, the Li foil from the half coin cell was removed, and one additional spacer was added. This resulted in the fabrication of a symmetric cell, which was used to evaluate the physical properties of Comparative Example 3.

Symmetric cells were fabricated using, as electrode plates, the metal layers manufactured in Example 1, Comparative Example 2, and Comparative Example 3. Each symmetric cell was underwent charge/discharge testing at a current density of 1 mA/cm² and a capacity of 1 mAh/cm² for a total duration of 500 hours, and the results are shown in FIG. 3.

Referring to FIG. 3, in the case of Comparative Example 1, the average overvoltage during continuous charge/discharge for 500 hours was 1.83 V, and there were sections where voltage peaks appeared during measurement, indicating an unstable voltage range.

On the contrary, in the case of Example 1, the average overvoltage during 500 hours of charge/discharge was 1.29 V, indicating a stable voltage range. Moreover, it maintained voltage stability without long-term voltage peaks, demonstrating a 29% improvement in voltage range compared to Comparative Example 1. Both Comparative Examples 2 and 3 were found to produce inferior results compared to Comparative Example 1.

While this disclosure has been described in connection with what is presently considered to be practical embodiments, it is to be understood that the disclosure is not limited to the disclosed embodiments. On the contrary, it is intended to cover various modifications and equivalent arrangements included within the spirit and scope of the appended claims.

What is claimed is:

1. A method of manufacturing a metal layer, the method comprising:
a copper foil manufacturing step of forming a copper layer as an electroplated layer using a plating solution containing a copper precursor and a leveler; and
a coating step of forming a gold coating layer on a surface of the copper layer, thereby manufacturing a metal layer,
wherein the leveler includes JGB (Janus green B, C₃₀H₃₁ClN₆),
the plating solution contains the leveler in an amount of greater than 10 μmol to equal to or less than 40 μmol based on 1 mol of copper in the copper precursor, and
the metal layer has a roughness average (Ra) of equal to or less than 50 nm, as measured on a surface of the gold coating layer.

2. The method of claim 1, wherein the coating step is carried out by a sputtering method using a gold target.

3. The method of claim 1, wherein the gold coating layer has a thickness of equal to or less than 6 nm.

4. The method of claim 1, wherein the metal layer has a ten point average roughness (Rz) of equal to or less than 500 nm.

5. The method of claim 1, wherein the gold coating layer has a surface structure in which gold nanoparticles are embedded.

6. The method of claim 1, wherein the metal layer suppresses lithium dendrite growth on the metal layer when used as a negative electrode current collector of a lithium battery.

7. A metal layer for a lithium battery current collector, the metal layer comprising:
a copper layer; and
a gold coating layer disposed on a surface of the copper layer,
wherein the metal layer has a roughness average (Ra) of equal to or less than 50 nm, as measured on a surface of the gold coating layer.

8. The metal layer of claim 7, wherein the metal layer, when used as a negative electrode current collector of a lithium battery, maintains a voltage range of −1.5 to +1.5 V relative to a reference voltage during cycling performance testing of 0 to 500 hours.
